(19) United States
(12) Patent Application Publication
(10) Pub. No.: US 2025/0275321 A1
(43) Pub. Date: Aug. 28, 2025

(54) MICRO LED DISPLAY PANEL AND MANUFACTURING METHOD THEREOF

(71) Applicant: AUO Corporation, Hsinchu City (TW)

(72) Inventors: Wen-Chiuan Su, Hsinchu City (TW); Yu-Chi Hsiao, Hsinchu City (TW); Ling-Ying Chien, Hsinchu City (TW)

(73) Assignee: AUO Corporation, Hsinchu City (TW)

(21) Appl. No.: 18/822,478

(22) Filed: Sep. 3, 2024

(30) Foreign Application Priority Data
Feb. 23, 2024 (TW) 113106543

(51) Int. Cl. H01L 33/62; H01L 25/16

(52) U.S. Cl. CPC H10H 20/857; H01L 25/167; H10H 20/0364

(57) ABSTRACT

A micro LED display panel includes a circuit substrate, multiple vertical micro LEDs, a substrate, multiple bumps, and a transparent conductive layer. Each vertical micro LED is electrically connected to the circuit substrate by a first electrode thereof. The bumps are disposed on a surface of the substrate, and respectively correspond to second electrodes of the vertical micro LEDs. The transparent conductive layer is disposed on the surface of the substrate, and the bumps are located between the transparent conductive layer and the substrate. Each vertical micro LED is electrically connected to the transparent conductive layer by the second electrode thereof. A manufacturing method of a micro LED display panel is also provided.

### CROSS-REFERENCE TO RELATED APPLICATION

This application claims the priority benefit of Taiwan application serial no. 113106543, filed on Feb. 23, 2024. The entirety of the above-mentioned patent application is hereby incorporated by reference herein and made a part of this specification.

### BACKGROUND

### Technical Field

The disclosure relates to a micro LED display panel and a manufacturing method thereof.

### Description of Related Art

In a traditional process of manufacturing a micro LED display panel, a test on whether each micro LED can be normally turned on is performed. However, when the micro LED is a vertical micro LED, each vertical micro LED needs to be covered with a flat layer, and a transparent conductive layer ITO is disposed on the flat layer, to complete an electrical connection disposal of each vertical micro LED and also to perform a lighting test. Under such conditions, even if a micro LED that needs to be replaced is found due to the test, the micro LED covered by the flat layer is not easy to be replaced that leads to complex process steps and increases manufacturing costs.

### SUMMARY

The disclosure provides a manufacturing method of a micro LED display panel. The process steps are simple, and the manufacturing cost is significantly reduced. The micro LED display panel that is manufactured based on the manufacturing method has good production yield.

Based on an embodiment of the disclosure, a manufacturing method of a micro LED display panel is provided that includes disposing multiple vertical micro LEDs in a matrix manner on a circuit substrate; disposing multiple bumps on a substrate; disposing a first transparent conductive layer on the bumps and the substrate; pairing the circuit substrate and the substrate to allow the bumps to respectively correspond to the vertical micro LEDs and the first transparent conductive layer to be electrically connected to electrodes of the vertical micro LEDs; electrically connecting the first transparent conductive layer and a test device; and testing the vertical micro LEDs with the test device.

Based on another embodiment of the disclosure, a micro LED display panel is provided that includes a circuit substrate, multiple vertical micro LEDs, a substrate, multiple bumps, and a transparent conductive layer. Every vertical micro LED includes a first electrode and a second electrode. Each vertical micro LED is electrically connected to the circuit substrate by the first electrode. The substrate includes a surface facing the circuit substrate. The bumps are disposed on the surface and respectively correspond to the second electrodes. The transparent conductive layer is disposed on the surface, and the bumps are located between the transparent conductive layer and the substrate. Each vertical micro LED is electrically connected to the transparent conductive layer by the second electrode.

Based on the above, based on the manufacturing method of the micro LED display panel provided by the embodiment of the disclosure, the bumps, that respectively correspond to the vertical micro LEDs, disposed on the substrate and the transparent conductive layer on the bumps are utilized to form a test path to allow the test device to test by the test path whether the vertical micro LEDs can be normally turned on, and to allow a damaged vertical micro LED to be promptly removed and replaced with a vertical micro LED that can be normally turned on. Every vertical micro LED is tested before a photolithography process of manufacturing a flat layer to avoid a condition where the vertical micro LED is covered by the flat layer and is difficult to be replaced. Accordingly, the micro LED display panel provided based on the embodiment of the disclosure may have good production yield. Moreover, the substrate, the bumps and the transparent conductive layer that are formed as the test path in the manufacturing steps may further be eventually formed as a part of the micro LED display panel. The process steps are simple, and the manufacturing cost is significantly reduced.

In order to make the features and advantages of the disclosure more comprehensible, the following examples are given and described in detail with the accompanying drawings as follows.

### BRIEF DESCRIPTION OF THE DRAWINGS

FIG. 1A to FIG. 1D illustrate schematic diagrams corresponding to steps of a manufacturing method of a micro LED display panel based on some embodiments of the disclosure.

FIG. 2A to FIG. 2C illustrate schematic diagrams corresponding to steps of a manufacturing method of a micro LED display panel based on a first embodiment of the disclosure.

FIG. 3A and FIG. 3B illustrate schematic diagrams corresponding to steps of a manufacturing method of a micro LED display panel based on a second embodiment of the disclosure.

### DESCRIPTION OF THE EMBODIMENTS

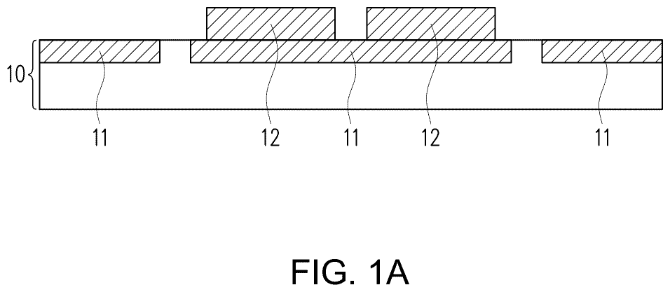

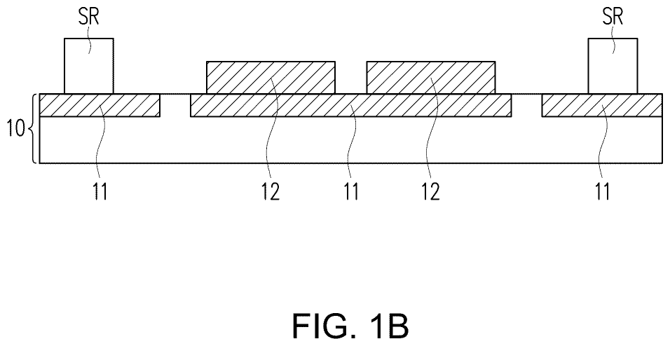

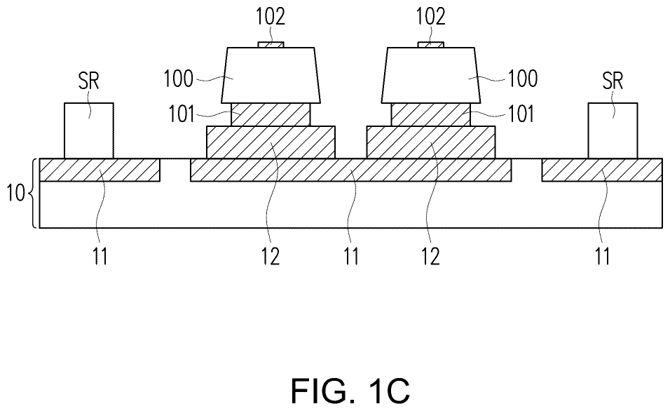

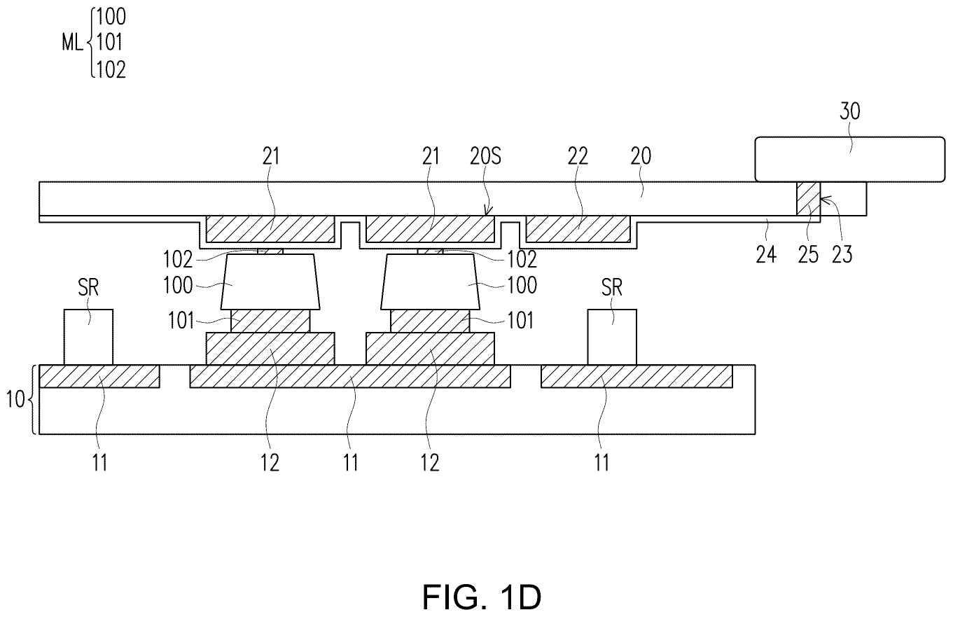

Referring to FIG. 1A to FIG. 1D, schematic diagrams corresponding to steps of a manufacturing method of a micro LED display panel based on some embodiments of the disclosure are illustrated thereof.

Referring to FIG. 1A, a circuit substrate 10 includes a circuit layer 11, on which is provided with multiple conductive bumps 12 that are connected to the circuit layer 11. Referring to FIG. 1B, multiple spacing members SR are disposed on the circuit substrate 10. Referring to FIG. 1C, multiple vertical micro LEDs ML are disposed in a matrix manner on the circuit substrate 10. Every vertical micro LED ML includes a body 100, an electrode 101, and an electrode 102. Every vertical micro LED ML is connected to the corresponding conductive bump 12 and the circuit layer 11 by the electrode 101.

Referring to FIG. 1D, multiple bumps 21 and at least one conductive bump 22 are disposed on a surface 20S of a substrate 20. A via 23 is formed by mechanical drilling, and a metal material 25 is disposed therein. Moreover, a transparent conductive layer 24 is disposed on the bumps 21 and the at least one conductive bump 22, and the transparent conductive layer 24 and the metal material 25 in the via 23 are electrically connected. Then, the circuit substrate 10 and the substrate 20 are paired to allow the bumps 21 to respectively correspond to the vertical micro LEDs ML. The transparent conductive layer 24 is electrically connected to the electrodes 102 of the vertical micro LEDs ML. Finally, a test device 30 is electrically connected to the transparent conductive layer 24, and the test device 30 tests whether the vertical micro LEDs ML can be turned on. The test device 30 may be implemented by one or multiple circuits. By a test result of the test device 30, a damaged vertical micro LED ML may be removed from the circuit substrate 10 and replaced with a vertical micro LED ML that can be normally turned on.

It should be noted that, in some embodiments, the substrate 20 is not provided with the via 23, and the test device 30 may be directly electrically connected to the transparent conductive layer 24. In addition, a material of the conductive bump 22 in FIG. 1D may include metal to reduce impedance, but the disclosure is not limited thereto. In some embodiments, the substrate 20 may not be provided with the conductive bump 22.

It should be noted that, in the embodiment, the bumps 21, that respectively correspond to the vertical micro LEDs ML, disposed on the substrate 20 and the transparent conductive layer 24 on the bumps 21 are utilized to form a test path to allow the test device 30 to test by the test path whether the vertical micro LEDs ML can be normally turned on, and to allow a damaged vertical micro LED ML to be promptly removed and replaced with a vertical micro LED ML that can be normally turned on. The bumps 21 are compressible to compensate for a height difference of the vertical micro LEDs ML in a normal direction of the circuit substrate 10 to allow good electrical connection between every vertical micro LED ML and the test device 30. In some embodiments, a material of the bumps 21 may include metal and may be conductive, but the disclosure is not limited thereto. In some embodiments, the bumps 21 may be non-conductive.

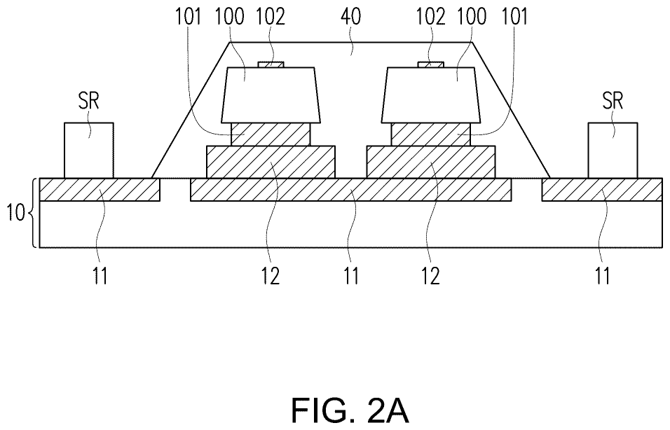

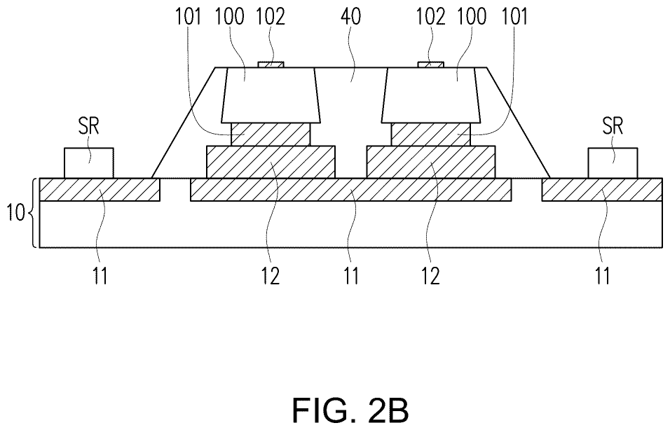

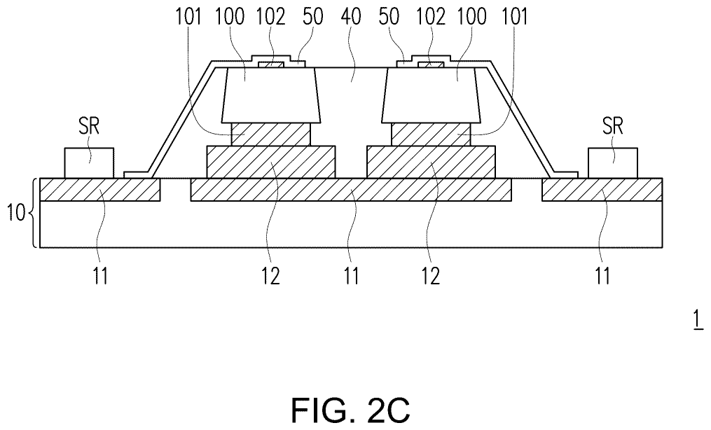

Referring to FIG. 2A to FIG. 2C, schematic diagrams corresponding to steps of a manufacturing method of a micro LED display panel based on a first embodiment of the disclosure are illustrated thereof. Specifically, in the first embodiment, steps of FIG. 2A to FIG. 2C are continued from the steps of FIG. 1A to FIG. 1D to complete a micro LED display panel 1 that is to be described below.

Referring to FIG. 1D, FIG. 2A and FIG. 2B, after the vertical micro LEDs ML on the circuit substrate 10 are confirmed all to be able to be normally turned on by the test device 30, the test device 30 and the substrate 20 are removed. As shown in the FIG. 2A and FIG. 2B, photolithography processes, such as photoresist, exposure and development, and ash, are performed to dispose a flat layer 40 that covers the vertical micro LEDs ML on the circuit substrate 10, and to remove part of the flat layer 40 on the vertical micro LEDs ML to expose the electrodes 102 of the vertical micro LEDs ML from the flat layer 40. Finally, as shown in FIG. 2C, a transparent conductive layer 50 (such as ITO) is disposed to allow the electrode 102 of every vertical micro LED ML to be electrically connected to the circuit layer 11. Accordingly, the micro LED display panel 1 is completed.

It should be particularly noted that, in a manufacturing method of a micro LED display panel provided based on a Comparative Example, the substrate 20 and the bumps 21 thereon and the transparent conductive layer 24 are not used to form a test path. The vertical micro LEDs ML disposed on the circuit substrate 10 need to form a test path to be electrically connected to the test device 30 to perform test by the electrodes 102 and the transparent conductive layer 50 after the steps shown in the foregoing FIG. 2C. However, as shown in FIG. 2C, every vertical micro LED ML is covered by the flat layer 40 and is difficult to be replaced that results in a decrease in yield. In contrast, every vertical micro LED ML in the micro LED display panel 1 provided based on the first embodiment of the disclosure is tested in the aforementioned process steps before being covered by the flat layer 40 to avoid a condition where the vertical micro LED ML is covered by the flat layer 40 and is difficult to be replaced. The production yield of the micro LED display panel 1 is significantly increased.

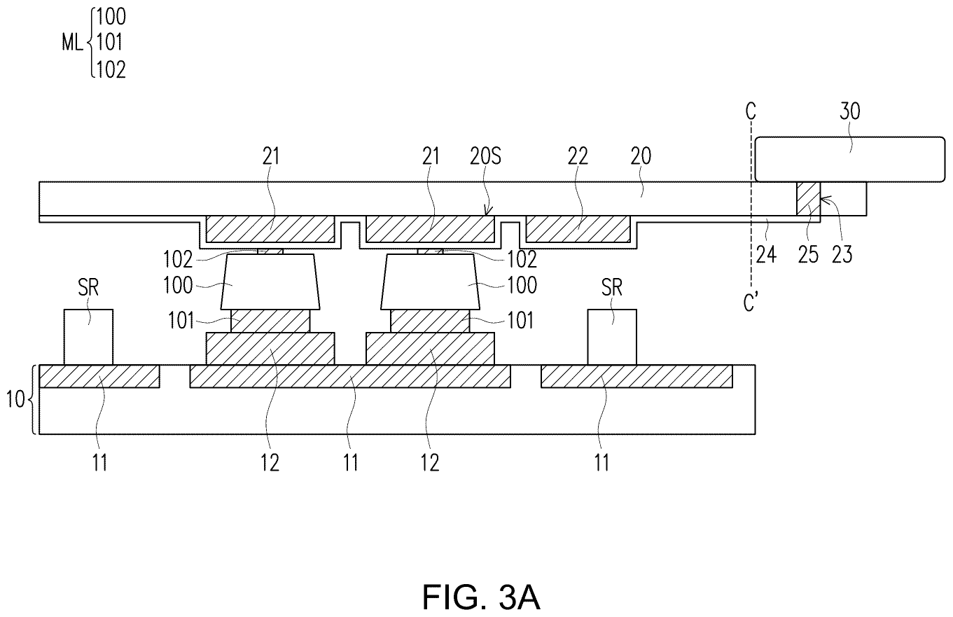

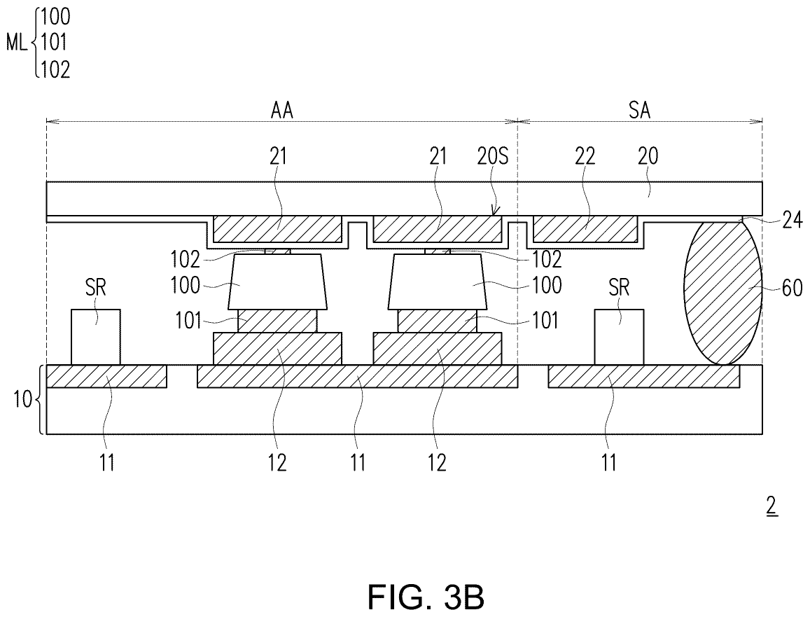

Referring to FIG. 3A and FIG. 3B, schematic diagrams corresponding to steps of a manufacturing method of a micro LED display panel based on a second embodiment of the disclosure are illustrated thereof. Specifically, in the second embodiment, steps of FIG. 3A and FIG. 3B are continued from the steps of FIG. 1A to FIG. 1D to complete a micro LED display panel 2 that is to be described below.

Referring to FIG. 1D and FIG. 3A, after the vertical micro LEDs ML on the circuit substrate 10 are confirmed all to be able to be normally turned on by the test device 30, as shown by a dotted line CC′ in FIG. 3A, the substrate 20 is cut to remove the via 23 and the test device 30. Finally, referring to FIG. 3B, a conductive bump 60 is disposed between the circuit substrate 10 and the substrate 20 to electrically connect the transparent conductive layer 24 and the circuit layer 11. Accordingly, the micro LED display panel 2 is completed.

It should be particularly noted that, in the second embodiment, the bumps 21, that respectively correspond to the vertical micro LEDs ML, disposed on the substrate 20 and the transparent conductive layers 24 on the bumps 21 are utilized to form a test path to allow the test device 30 to test by the test path whether the vertical micro LEDs ML can be normally turned on, and to allow a damaged vertical micro LED ML to be promptly removed and replaced with a vertical micro LED ML that can be normally turned on. The production yield of the micro LED display panel 2 is significantly increased.

As shown in FIG. 3B, the micro LED display panel 2 provided based on the second embodiment of the disclosure includes a circuit substrate 10, multiple vertical micro LEDs ML, a substrate 20, multiple bumps 21, and a transparent conductive layer 24. Every vertical micro LED ML is located in an active region AA of the micro LED display panel 2 and includes an electrode 101 and an electrode 102. Each vertical micro LED ML is electrically connected to the circuit substrate 10 by the electrode 101 thereof. The substrate 20 includes a surface 20S that faces the circuit substrate 10. The bumps 21 are disposed on the surface 20S and respectively correspond to the electrodes 102. The transparent conductive layer 24 is disposed on the surface 20S, and the bumps 21 are located between the transparent conductive layer 24 and the substrate 20. Every vertical micro LED ML is electrically connected to the transparent conductive layer 24 by the electrode 102 thereof.

It should be particularly noted that part of the structure of the micro LED display panel 2 (such as the substrate 20, the bumps 21, and the transparent conductive layer 24) is formed as the test path in the aforementioned manufacturing steps, and is eventually formed as a part of the micro LED display panel 2. In other words, the micro LED display panel 2 may have good production yield, and the process steps are simple, and the manufacturing cost is significantly reduced.

The micro LED display panel 2 may further include at least one conductive bump 60. Each vertical micro LED ML is electrically connected to the circuit substrate 10 by the conductive bump 60, and the conductive bump 60 is disposed in a sealant region SA of the micro LED display panel 2.

The micro LED display panel 2 may further include at least one conductive bump 22 that is disposed between the conductive bump 60 and the bumps 21, and is located in the sealant region SA of the micro LED display panel 2. The conductive bump 22 may include metal to reduce impedance, and a vertical projection thereof on the circuit substrate 10 does not overlap with a vertical projection of the vertical micro LEDs ML on the circuit substrate 10, as shown in FIG. 3B.

In summary, based on the manufacturing method of the micro LED display panel provided by the embodiment of the disclosure, the bumps, that respectively correspond to the vertical micro LEDs, disposed on the substrate and the transparent conductive layer on the bumps are utilized to form a test path to allow the test device to test by the test path whether the vertical micro LEDs can be normally turned on, and to allow a damaged vertical micro LED to be promptly removed and replaced with a vertical micro LED that can be normally turned on. Every vertical micro LED is tested before the photolithography process of manufacturing the flat layer to avoid a condition where the vertical micro LED is covered by the flat layer and is difficult to be replaced. Accordingly, the micro LED display panel provided based on the embodiment of the disclosure may have good production yield. In addition, the substrate, the bumps and the transparent conductive layer formed as the test path in the manufacturing steps may further be eventually formed as a part of the micro LED display panel. The process steps are simple, and the manufacturing cost is significantly reduced.

What is claimed is:

1. A manufacturing method of a micro LED display panel, comprising:
disposing a plurality of vertical micro LEDs in a matrix manner on a circuit substrate;
disposing a plurality of bumps on a substrate;
disposing a first transparent conductive layer on the bumps and the substrate;
pairing the circuit substrate and the substrate to allow the bumps to respectively correspond to the vertical micro LEDs, and the first transparent conductive layer to be electrically connected to electrodes of the vertical micro LEDs;
electrically connecting the first transparent conductive layer and a test device; and
testing the vertical micro LEDs with the test device.

2. The manufacturing method of the micro LED display panel according to claim 1, further comprising:
removing a damaged vertical micro LED from the circuit substrate.

3. The manufacturing method of the micro LED display panel according to claim 1, further comprising:
drilling the substrate to form a via, wherein the test device is electrically connected to the first transparent conductive layer by the via.

4. The manufacturing method of the micro LED display panel according to claim 3, further comprising:
cutting the substrate to remove the via.

5. The manufacturing method of the micro LED display panel according to claim 1, further comprising:
disposing a flat layer on the circuit substrate, wherein the flat layer covers the vertical micro LEDs;
removing part of the flat layer on the vertical micro LEDs to allow the electrodes of the vertical micro LEDs to be exposed from the flat layer; and
disposing a second transparent conductive layer on the vertical micro LEDs, wherein the second transparent conductive layer is electrically connected between the electrodes of the vertical micro LEDs and the circuit substrate.

6. The manufacturing method of the micro LED display panel according to claim 1, further comprising:
disposing a conductive bump between the circuit substrate and the substrate, wherein the first transparent conductive layer is electrically connected to the circuit substrate by the conductive bump.

7. A micro LED display panel, comprising:
a circuit substrate;
a plurality of vertical micro LEDs, wherein each of the vertical micro LEDs comprises a first electrode and a second electrode, and each of the vertical micro LEDs is electrically connected to the circuit substrate by the first electrode;
a substrate, comprising a surface facing the circuit substrate;
a plurality of bumps, disposed on the surface, and respectively corresponding to the second electrodes;
a transparent conductive layer, disposed on the surface, wherein the bumps are located between the transparent conductive layer and the substrate, and each of the vertical micro LEDs is electrically connected to the transparent conductive layer by the second electrode; and
at least one first conductive bump, wherein each of the vertical micro LEDs is electrically connected to the circuit substrate by the at least one first conductive bump.

8. The micro LED display panel according to claim 7, wherein the at least one first conductive bump is located in a sealant region of the micro LED display panel.

9. The micro LED display panel according to claim 8, further comprising at least one second conductive bump, disposed between the at least one first conductive bump and the bumps, and located in the sealant region of the micro LED display panel, wherein a vertical projection of the at least one second conductive bump on the circuit substrate does not overlap with a vertical projection of the vertical micro LEDs on the circuit substrate.
